(19) United States
(12) Patent Application Publication
(10) Pub. No.: US 2024/0120312 A1
(43) Pub. Date: Apr. 11, 2024

(54) SHIFTED MULTI-VIA CONNECTION FOR HYBRID BONDING

(71) Applicant: Tokyo Electron Limited, Tokyo (JP)

(72) Inventor: Kevin RYAN, Albany, NY (US)

(73) Assignee: Tokyo Electron Limited, Tokyo (JP)

(21) Appl. No.: 18/373,098

(22) Filed: Sep. 26, 2023

Related U.S. Application Data
(60) Provisional application No. 63/413,388, filed on Oct. 5, 2022.

(51) Int. Cl. H01L 23/00; H01L 21/66; H01L 25/065; H01L 21/822

(52) U.S. Cl. CPC H01L 24/80; H01L 22/14; H01L 24/08; H01L 25/0655; H01L 21/8221; H01L 2224/08121; H01L 2224/08235; H01L 2224/80895; H01L 2224/80896; H01L 2924/37001; H01L 2924/381

(57) ABSTRACT

Shifted multi-via connections are disclosed. A method includes providing a first contact array structure on a first substrate. The first contact array structure includes a plurality of first contacts. The method includes providing a second contact array structure on a second substrate. The second contact array structure includes a plurality of second contacts configured to interface with the plurality of first contacts. The method includes bonding the first substrate to the second substrate. Portions of the first contact array structure, the second contact array structure or both the first and second contact array structures are intentionally shifted to compensate for misalignment that occurs during the bonding of the first substrate to the second substrate.

### CROSS-REFERENCE TO RELATED APPLICATIONS

This disclosure claims priority to U.S. Provisional Patent Application No. 63/413,388, filed Oct. 5, 2022, which is incorporated herein by reference in its entirety for all purposes.

### TECHNICAL FIELD

This disclosure relates to microelectronic devices including semiconductor devices, transistors, and integrated circuits, including methods of microfabrication.

### BACKGROUND

The bonding of layers to form 3D structures is of growing importance in the semiconductor manufacturing industry. For example, semiconductor wafers or reconstituted wafers may be generated with circuit components such as logic, memory and/or passive devices. In order to combine devices in the z-plane, multiple wafers may be bonded together by a bonding process. In some instances, electrical connections are provided on each substrate and connected as part of the bonding process in what is generally termed hybrid bonding. The connections may be provided as copper (Cu) pads and may have a small size and/or pitch (e.g., 5-micron pitch and/or feature size and below). Due to material characteristics and manufacturing challenges, alignment of these fine features can be difficult. The Cu hybrid bonding process is generally considered to have misalignment variability of the top and bottom vias that will be a continuing challenge. Moreover, as bonding pad dimensions shrink to finer feature sizes, the yield window due to high connection resistance will also be reduced. Thus, as hybrid bonding pitches shrink to 1 micron and below, precise alignment will become more critical and providing a yield enhancement that can compensate for misalignment will be beneficial.

### SUMMARY

Described herein are structures and techniques that provide or improve 3D structures and circuits created using hybrid bonding. As hybrid bonding via/contact pitch sizes are decreased the alignment will become more critical across the entire wafer. With these smaller pitches the resistance of the conductive interfaces of circuits will deviate more severely and make multi-via connection more critical to maintain yield. The techniques described herein improve the yield of wafer to wafer (or panel to panel) bonded technology to reduce resistance variation induced by top and bottom wafer contact misalignment.

According to techniques described here, nominal locations for vias may be intentionally shifted in order to compensate for misalignment between an upper and lower wafer. More particularly, the top and/or bottom via alignment may be purposefully shifted in the design to enable more robust yield window for connection resistance shifts. This technique can reduce yield degradation associated with smaller pitch bonding pads. These techniques for 3D and heterogenous integration can improve power-performance-area (PPA) metrics, both by decreasing resistive losses in at least some instances, and by densifying connections (e.g., employing smaller contact pads).

In one embodiment, a method may include providing a first contact array structure on a first substrate. The first contact array structure includes a plurality of first contacts. The method includes providing a second contact array structure on a second substrate. The second contact array structure includes a plurality of second contacts configured to interface with the plurality of first contacts. The method includes bonding the first substrate to the second substrate. Portions of the first contact array structure, the second contact array structure or both the first and second contact array structures are intentionally shifted to compensate for misalignment, such as that that occurs during the bonding of the first substrate to the second substrate.

The first substrate may be a wafer. The first substrate may be a panel comprising a plurality of semiconductor dies.

The first contact array structure may comprise bonding pads with a bonding pad pitch, the method further comprising purposefully shifting a via-structure pattern on at least one of the first and second substrate to specified distances based on the bonding pad pitch.

The first contact array structure may comprise multi-via connections with pattern shifts provided either in a regular array structure or in a disaggregated assortment across the bonding interface.

The plurality of first contacts may include a plurality of bonding pads laterally spaced according to a same bonding pad pitch. The bonding pad pitch can be different than a corresponding bonding pad pitch of the plurality of second contacts.

The first contact array structure may not include two contacts laterally separated by other contacts of the first substrate.

The first contact array structure may include two contacts laterally separated by other contacts of the first substrate.

The first substrate may comprise a third contact array structure configured to electrically connect to a fourth contact array structure of the second substrate. The third contact array structure can be disposed radially outward from the first contact array structure. A nominal offset of the third contact array structure, relative to the fourth contact array structure, can exceed a nominal offset of the first contact array structure, relative to the second contact array structure.

The method may include detecting an indication of an impedance between the first contact array structure and the second contact array structure.

In another embodiment, a system may include a first substrate including multiple first contacts of a first contact array structure, the first contacts coupled to a first net of the first substrate. The system includes a second substrate including multiple second contacts of a second contact array structure, the second contacts coupled to a second net of the second substrate. The second contact array structure is configured to interface with the first contact array structure. The first contacts are offset from corresponding second contacts.

The first contact array structure may include a contact configured to connect to a corresponding contact of the second contact array structure, and not offset from the corresponding contact.

A first one of the first contacts may be configured to couple with a first one of the second contacts, according to an off-nominal position of the first substrate relative to the second substrate, the coupling associated with a first resistance. The first one of the first contacts can be configured to couple with the first one of the second contacts, according to a nominal position of the first substrate relative to the second substrate; the coupling is associated with a second resistance less than the first resistance.

A lateral dimension, along a first lateral axis, of a first one of the plurality of first contacts may exceed a magnitude of the offset from a corresponding one of the plurality of second contacts.

A quantity of the first contacts may be equal to a quantity of the second contacts.

Each of the plurality of first contacts may have a same footprint; and each of the plurality of second contacts may have the same footprint.

The plurality of first contacts may be separated by a same dimension along a lateral axis.

In yet another embodiment, a semiconductor device may include a first substrate. The semiconductor device includes a second substrate bonded to the first substrate along a bonding plane. The first substrate includes a first contact array structure. The first contact array structure includes a first contact configured to interface with a second contact of the second substrate. The first contact array structure includes a third contact configured to interface with a fourth contact of the second substrate, the first contact and the second contact spaced a first distance along a first axis of the bonding plane. The second substrate includes a second contact array structure including the second contact, and the fourth contact. The second contact and the fourth contact are spaced a second distance, different from the first distance, along the first axis of the bonding plane.

The semiconductor device may include a fifth contact of the first substrate configured to interface with a sixth contact of the second substrate. The fifth contact is spaced from the first contact a third distance along a second axis of the bonding plane, different from the first axis. The sixth contact is spaced from the second contact a fourth distance, different from the third distance, along the second axis.

The first distance may be equal to the third distance. The second distance can be equal to the fourth distance. The first axis can be perpendicular to the second axis.

The first substrate may be a wafer. The wafer can include a third contact array structure disposed radially outward from the first contact array structure. The third contact array structure can include contacts spaced by a third distance, greater than the first distance.

At least one of the first substrate or the second substrate may be a panel comprising a plurality of semiconductor dies.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise. References to “or” may be construed as inclusive so that any terms described using “or” may indicate any of a single, more than one, and all of the described terms.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a pair of substrates to be bonded and electrically connected, in accordance with some embodiments.

FIG. 2 illustrates an isometric ghosted cutaway top view of respective nominal positions of various contacts of paired contact array structures, in accordance with some embodiments.

FIG. 3A illustrates an isometric ghosted cutaway top view of a nominal alignment of paired contact array structures, in accordance with some embodiments.

FIGS. 3B, 3C, and 3D illustrate off-nominal alignments of the paired contact array structure of FIG. 3A, in accordance with some embodiments.

FIG. 4 illustrates a cross sectional view of a bonded substrate pair including paired contact array structures, in accordance with some embodiments.

FIG. 5A illustrates a cross sectional view of a bonded substrate pair including paired contact array structures, in accordance with some embodiments.

FIGS. 5B and 5C illustrate off-nominal alignments of the paired contact array structures of FIG. 5A, in accordance with some embodiments.

FIG. 6 is a graphical depiction of yield corresponding to contact array structures, in accordance with some embodiments.

FIG. 7 is a flow chart of a method for making a semiconductor device, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Disclosed herein are embodiments related to one or more structures having an upper portion and a lower portion wherein each portion is associated with a semiconductor substrate. In some embodiments, the structures can include a via structure such as an interlayer via and a conductive structure such as a lateral conductive element of a metallization layer of a semiconductor substrate. The structures can include one or more conductive pads accessible by a test instrument to determine a performance characteristic thereof such as an impedance. For example, the impedance can be related to an offset such that an offset can be determined for a portion of a semiconductor device comprising the structure.

Reference will now be made to the figures, which for the convenience of visualizing the semiconductor devices described herein, illustrate substrates undergoing process flows in both top and cross-sectional views. In the top and cross-sectional views of the figures, connections between conductive layers or materials may be shown. However, it should be understood that these connections between various layers and masks are merely illustrative and are intended to show a capability for providing such connections and should not be considered limiting to the scope of the claims. Further, offsets can be relative to an intended location of a corresponding terminal (e.g., assuming perfectly aligned substrates and layers disposed there over) or can illustrate a deviation from an intended location of a corresponding terminal. An alignment can be determined based on the relative difference (or lack thereof) between the intended and actual location of the corresponding terminals of interest. Thus, offsets between two interfacing surfaces can be generated by adjusting the position of a feature on either or both surfaces, relative to a respective aligned position. As used herein, a respective aligned position refers to the position that a corresponding element a non-misaligned semiconductor device will interface with.

Although the figures and aspects of the disclosure may show or describe devices herein as having a particular shape, it should be understood that such shapes are merely illustrative and should not be considered limiting to the scope of the techniques described herein. For example, although certain figures show various via structures, alignment marks, or other electric structures in a rectangular configuration, other shapes are also contemplated, and indeed the techniques described herein may be implemented in any shape or geometry.

Corresponding contact array structures can be formed in substrates which are utilized for hybrid bonding. The respective contact array structures can include contacts corresponding to each other. At least a portion of the corresponding contacts can include nominally offset portions, such that a contact surface area of the nominal connection is less than for an aligned contact. However, for certain off-nominal connections, the nominally offset portions may better align with their corresponding contacts. By including various contacts which are nominally offset according to one or more axes, such as one or more axes of a cartesian or polar (e.g., radial) pattern, offsets in various directions may be compensated for. The offsets may be generally symmetric about one or more axes of the device, or may be asymmetric, such as based on a likelihood or criticality of an offset along one axis varying from another.

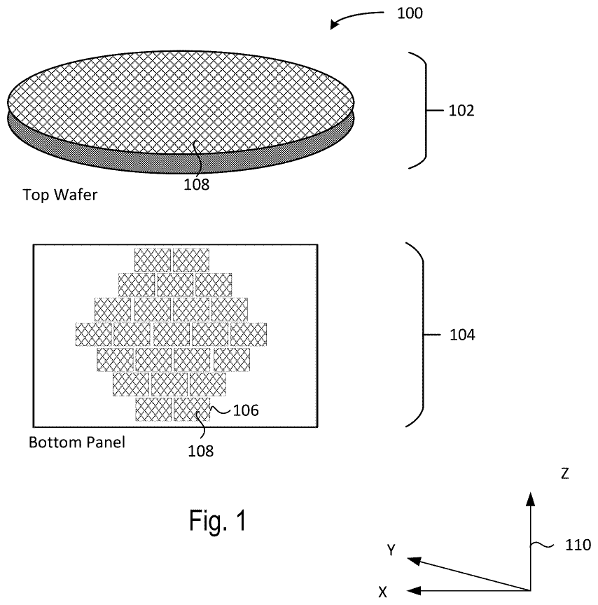

FIG. 1 illustrates a system 100 including a paired set of substrates configured for bonding, such as hybrid bonding. Particularly, the substrates include a top substrate, depicted as a semiconductor wafer 102, and a bottom substrate, depicted as a semiconductor panel 104 including various semiconductor dies 106 configured to interface to the wafer 102. For example, the various semiconductor dies 106 may be diced from one or more other wafers 102. Each substrate includes a contact array structure 108 of a paired set of contact array structures 108. That is, the respective contact array structures 108 of the respective substrates are configured to interface with each other, such as to stack a memory die over a logic die to form a three-dimensional integrated circuit (3DIC). The contact array structures 108 include contacts which are laterally offset from contacts of their corresponding contact array structures 108, such that for at least one contact of the contact array structures 108, a misalignment between the contact array structures 108 increases an alignment with a corresponding contact (e.g., decreases a resistance of a connection formed between the contact and a corresponding contact). That is, an intentional (purposeful) offset of a nominal design may become aligned according to an unintentional misalignment in an off-nominal position of a contact of a device, which may increase a yield or performance of bonded substrates including misaligned features.

The depicted substrates are merely an illustrative example and should not be construed as limiting. For example, in various embodiments, the upper and lower substrates may both be a semiconductor wafer 102 or both be a panel 104 or other assemblage of one or more semiconductor dies 106. Moreover, a relative position of one or more substrates may be modified or substituted. Indeed, phrases such as “upper,” “lower,” “right,” or “left” should be construed as describing the provided figures and are not intended to limit the scope of the present disclosure. Various embodiments can position the various elements described here according to various reference directions.

Misalignment between contacts occurs for a variety of reasons such as material expansion caused by temperature or CTE (coefficient of thermal expansion) mismatch, stretch or shift along a bond interface that may occur as the bonding interface is created and propagates across the substrate, warpage of either substrate, particle interference at the bond interface, or other sources of misalignment, without limiting effect. Moreover, the alignment may vary across various portions of the respective substrates. For example, in some embodiments, bonding originates at a center of the substrate, and misalignment (e.g., misalignment in excess of a threshold) is less probable at the center, and increasingly probable incident extending along a radial distance from the center of the substrate as bonding forces propagate outward. For example, a substrate can include multiple contact array structures 108 to connect to corresponding structures of another substrate. One contact array structure 108 can be disposed radially outward from another. The inner contact array structures 108 can include an offset which is less than an offset of the outer contact array structure 108 (each offset as relative to respective corresponding contact array structures 108 of the other substrate).

A provided axis 110 indicates an x-y plane, which may be referred to as a bonding plane, indicative of an interface between the respective substrates. Movement, distances, etc. which extend along the bonding plane are referred to, herein, as lateral movements, lateral distances, lateral dimensions, etc. A z-direction refers to a direction perpendicular to the bonding plane. Similar language, such as a z-height may also be referred to a device height according to a mounting surface or other substrate (e.g., a printed circuit board). Although such a z-height may generally correspond with the z-direction of the axis 110, such correspondence is not limiting and may, in some embodiments, differ therefrom.

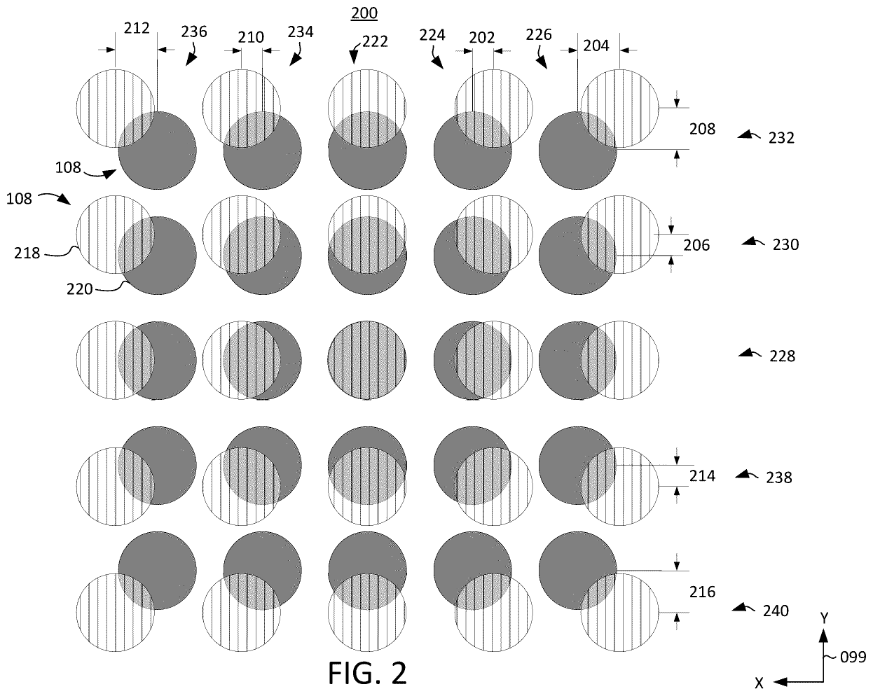

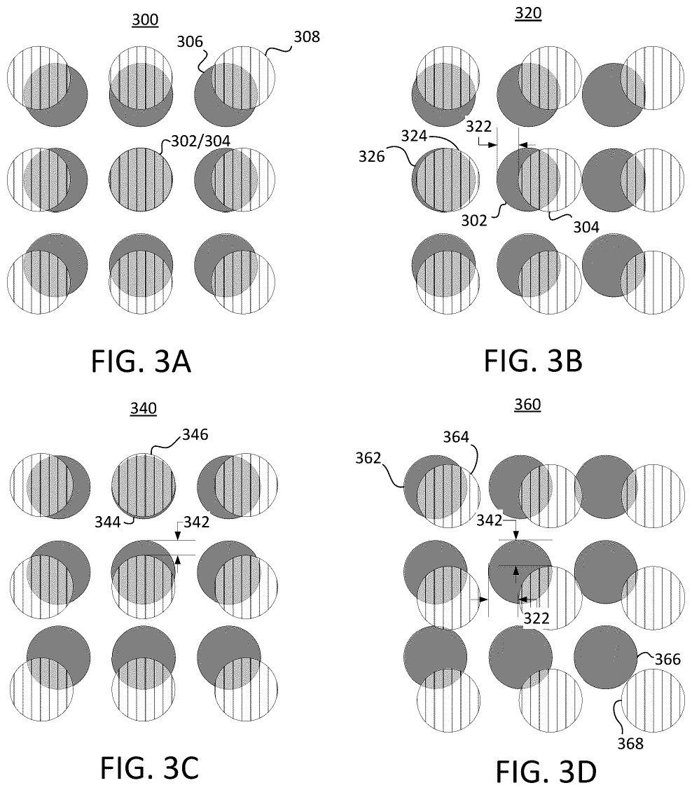

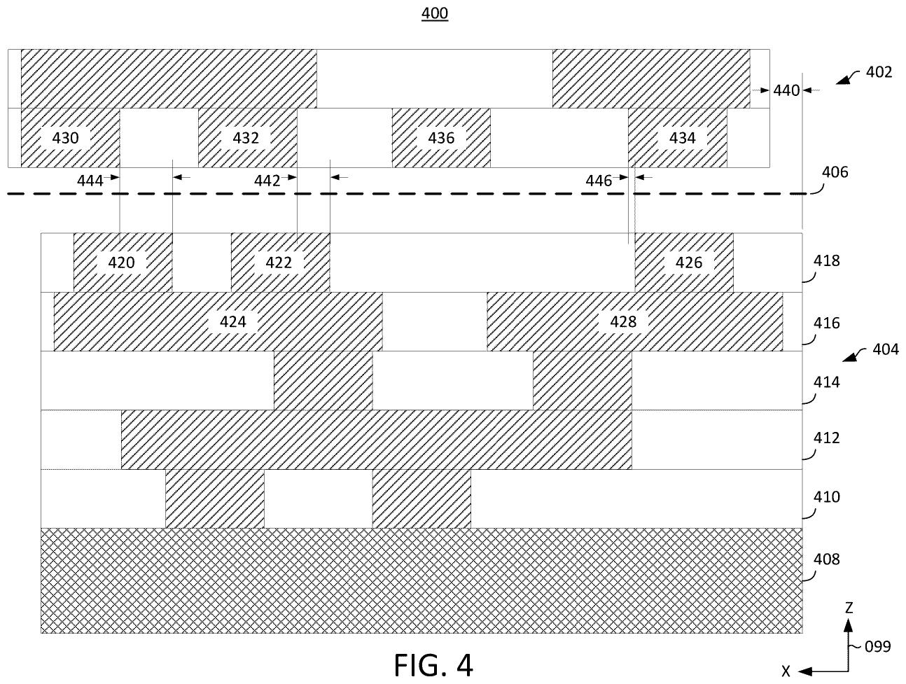

FIG. 2 illustrates an isometric ghosted top view 200 of respective nominal positions of various contacts 218, 220 of paired contact array structures 108, in accordance with some embodiments. The paired contact array structures 108 are configured to interface with each other along at least some of the various contacts 218, 220 thereof. A first set of contacts 218, depicted as shaded by a pattern of vertical lines, comprise constituent contacts 218 of a first contact array structure 108 (e.g., of an upper substrate). A second set of contacts 220, depicted according to a solid pattern, comprise constituent contacts 220 of a second contact array structure 108 (e.g., of a lower substrate). The nominal position refers to a position of the contacts according to zero-offset, zero-distortion coupling (e.g., a position as viewed according to an electronic design automation (EDA) tool) and does not necessarily correspond to any particular semiconductor device, which can include various misalignments such as the offsets of FIGS. 3B, 3C, and 3D, hereinafter.

As depicted, a centermost contact 218, 220 of each contact array structure 108 is aligned (e.g., is not offset from). Each contact can be or include a bonding pad (e.g., a surface to electrically connect with the other contact centermost contact 218, 220). A bonding pad can be flush with, recessed from (e.g., be impregnated within), or protrude from a face of the substrate (e.g., the bonding plane), according to various micro bumps, micropillars, or other connector geometries. A surface of the bonding pad along the bonding plane may be referred to as a footprint. For example, the depicted contacts 218, 220 include circular footprints. Various embodiments can include various footprints. One or more (e.g., all) contacts of a contact array structure 108 can include a same or different footprint as the other contacts of the same contact array structure 108, or a corresponding contact array structure 108. Footprints which are not the same can vary according to one or more lateral dimensions.

Some embodiments can include additional or fewer aligned contacts, or differently disposed contacts. For example, in some embodiments, the contact array structure 108 can be disaggregated (e.g., disposed over various portions of the bonding plane; contacts may not be positioned next to each other). For example, the contacts of a contact array structure 108 can be laterally separated by other contacts of the same substrate, either along a closed line segment between the contacts, or perpendicular thereto. The contacts of some contact array structures 108, as is depicted in FIG. 2, do not include such a disaggregation. A selection of a disaggregated or non-disaggregated connector-structure can, for example, achieve signal integrity (SI) targets for the device or reduce a coincidence of misalignment between the contacts (e.g., where distal portions of the respective substrates may suffer from a reduced coincidence of misalignment, relative to proximal portions).

Various other contacts 218, 220 of each contact array structure 108 are offset (e.g., intentionally shifted a specified distance), relative to each other. Particularly, each contact array structure 108 has a pattern arrayed into rows and columns; various other contact array structures 108 may be formed into various other sets of one or more contacts. For example, various contact array structures 108 can include contacts distributed according to a polygonal (e.g., hexagonal), radial (e.g., comprising concentric rings of contacts) or irregular patterns (e.g., distributed across the bonding plane). Various patterns can include contacts (e.g., bonding pads thereof) spaced according to a same or different bonding pad pitch. For example, as depicted, the first set of contacts 218 are spaced according to one nominal distance of a common bonding pad pitch along the x and y-axis 110; the second set of contacts 220 are spaced according to another nominal distance of another common bonding pad pitch along the x and y-axis 110.

In some embodiments, the contact array structures 108 can include non-symmetrical portions, such as for a portion of a wafer 102 which predominantly suffers misalignment in a predefined direction, or along a predefined axis. Moreover, in some embodiments, a number of contacts in each of a corresponding contact array structure 108 pair can include an unequal quantity of contacts, such as by nominally positioning one contact laterally separating two interfacing contacts, such that an offset in either direction can cause the one contact to connect to one of the two interfacing contacts. Other contact array structures 108, such as is depicted in FIG. 2, can include an equal quantity of contacts for the corresponding contact array structure 108.

A first column 222 of the contact array structures 108 is aligned along a first axis 110 of the bonding plane (e.g., the x-axis 110). A second column 224 of the contact array structures 108 is offset a first amount 202 along the first axis 110. A third column 226 is offset a second amount 204, having a greater magnitude than the first amount 202. A first row 228 of the contact array structures 108 is aligned along a second axis 110 of the bonding plane, perpendicular to the first axis (e.g., the x-axis 110). A second row 230 of the contact array structures 108 is offset a third amount 206 along the second axis 110. The magnitude of the third amount 206 may be equal to the first amount 202 (e.g., the depicted contact array structures 108 may be symmetrical). A third row 232 is offset a fourth amount 208, having a greater magnitude than the third amount 206. Although, as described above, contact array structures 108 according to some embodiments are not symmetrical, for brevity, a fourth column 234 and fifth column 236 are illustrated as offset a fifth amount 210 and a sixth amount 212, equal in magnitude and opposite in direction to the first amount 202 and the second amount 204, respectively. A fourth row 238 and fifth row 240 are illustrated as offset a seventh amount 214 and an eighth amount 216, equal in magnitude and opposite in direction to the third amount 206 and the fourth amount 208, respectively.

The nominal offsets (also referred to as shifts) of FIG. 2 may be provided in various forms including a shift coordinate table. A shift coordinator table includes a relative offset relative to a nominal contact (regardless whether a relative contact us present in a design). As depicted below, a shift coordinate table can describe the relative positions of the various contacts of FIG. 2, according to an arbitrary scale (left); an indication of the reference number employed in FIG. 2 is also provided [right].

| | | | | |
|---|---|---|---|---|
| (−2, 2) [212, 208] | (−1, 2) [210, 208] | (0, 2) [—, 208] | (1, 2) [204, 208] | (2, 2) [204, 208] |
| (−2, 1) [212, 206] | (−1, 1) [210, 206] | (0, 1) [—, 206] | (1, 1) [204, 206] | (2, 1) [204, 206] |
| (−2, 0) [212, —] | (−1, 0) [210, —] | (0, 0) [—, —] | (1, 0) [204, —] | (2, 0) [204, —] |
| (−2, −1) [212, 214] | (−1, −1) [210, 214] | (0, −1) [—, 214] | (1, −1) [204, 214] | (2, −1) [204, 214] |
| (−2, −2) [212, 216] | (−1, −2) [210, 216] | (0, −2) [—, 216] | (1, −2) [204, 216] | (2, −2) [204, 216] |

Referring now to FIG. 3A, an isometric ghosted top view 300 of a nominal alignment of paired contact array structures 108 is provided in accordance with some embodiments. Particularly, FIG. 3A illustrates an embodiment omitting the laterally extreme rows and columns of FIG. 2. For example, respective center contacts 302, 304 are depicted as aligned, and the upper right contacts 306, 308 are depicted as offset by the first amount 202 and the third amount 206 of FIG. 2.

FIGS. 3B, 3C, and 3D illustrate off-nominal alignments of the paired contact array structure 108 of FIG. 3A, in accordance with some embodiments. Particularly, FIG. 3B depicts a view 320 of a rightward shift or offset of the upper contacts, relative to the lower contacts. As depicted, the relatively tightly coupled contacts of the contact array structures 108 do not exhibit substantial variance in their respective offsets. Thus, a first amount 322 of the offset as measured at the center contacts 302, 304 is also exhibited by other contacts of the contact array structures 108. For example, as depicted, the left-center contacts 324, 326 exhibit greater alignment, which may correspond to lower resistance, improvement of various SI properties, and so forth. Conversely, oppositely disposed contacts may exhibit increased resistance, or may not connect to a corresponding contact at all. As shown, a lateral dimension of the various contacts can exceed a magnitude of a nominal or off-nominal offset between the contacts of at least one contact array structure 108, along one or more axes. That is, a lateral dimension of one or more of the plurality of contacts can exceed a magnitude of an expected offset. Accordingly, even substantial offsets can maintain at least some connection (e.g., a contact of a first contact array structure 108 can connect to a contact adjacent to a corresponding contact). For example, extending the first amount 322 of the offset can cause the left-center contact 324 of the upper contact array structure 108 to electrically connect with the center contact 302 of the lower contact array structure 108, such that logical connections are maintained, where the various contacts of the via structures are each assigned to a same net, the nets configured for connection with each other (e.g., to connect a power plane or other signal between various dies 106 of a 3DIC).

Referring now to FIG. 3C, another view 340 of an off-nominal alignment of the paired contact array structures 108 of FIG. 3A is provided in accordance with some embodiments. The depicted offset amount 342 is perpendicular to the offset amount 322 depicted in FIG. 3B, such that respective upper center contacts 344, 346 include a lowest resistance. However, a total resistance can include a contribution from each of the depicted contacts. Indeed, a design resistance can include a first portion corresponding to one or more most aligned contacts, and a second portion corresponding to one or more other contacts. In some embodiments, a detection circuit comprising marginal mis-aligned pads (e.g., pads configured to connect or not connect according to an offset) can detect an offset, such as to select one of a plurality of paths. For example, where SI attributes of a high resistance/high reflectivity are undesired, and the various contacts are connected to two or more nets, a signal may be preferentially provided to a net associated with the desired SI attributes, according to a detection of the test circuit. In some embodiments, a test pad connecting to a contact array structure 108 can be provided such that a test circuit separate from the bonded wafers 102 can be employed to detect an impedance or other signal path characteristic between the respective contact array structures 108. FIG. 3D depicts a view 360 of an example embodiment combining the offset amount 322 of FIG. 3B with the offset amount 342 of FIG. 3C. The offset causes a connection at the upper left contacts 362, 364 which exhibits reduced resistance, relative to an aligned connection, and a non-connection between the depicted bottom right contacts 366, 368.

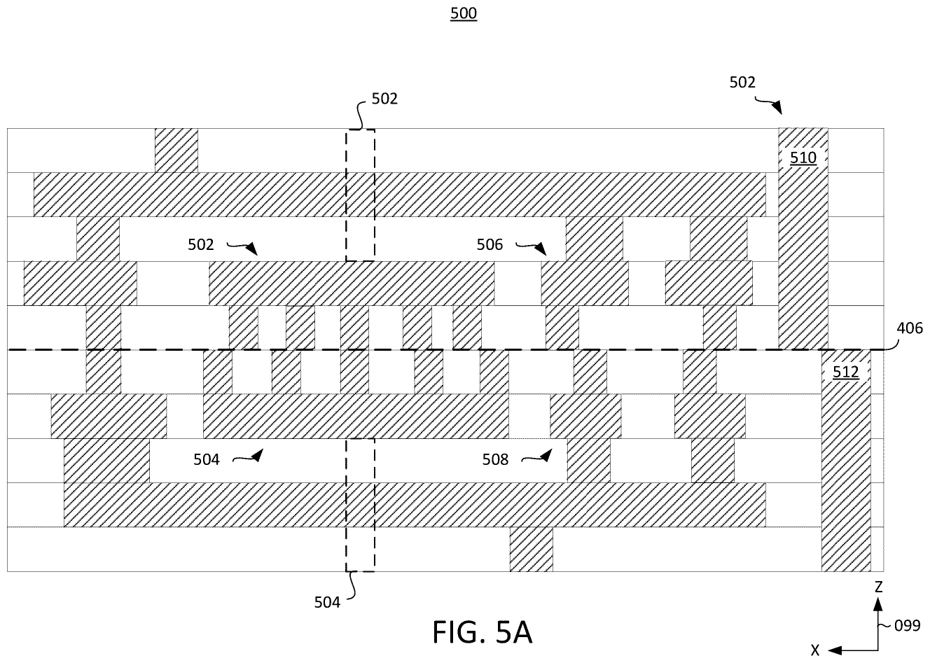

FIG. 4 illustrates a cross sectional view of a semiconductor device 400 including a bonded substrate pair, in accordance with some embodiments. The substrate pair includes a top substrate 402 (e.g., a panel 104 or wafer 102) and a bottom substrate 404 (e.g., a wafer 102 or panel 104). A junction of the top substrate 402 and bottom substrate 404 defines a bonding plane 406 which extends laterally upon a generally flat surface of the respective substrates, but which can include vertical variation according to warpage, deviations in thickness, or other attributes of the respective substrates 402, 404. The top 402 and bottom substrates 404 are shown separated, merely for ease of depiction of various features and spacings along the bonding plane 406. A misalignment of the depicted semiconductor device 400 is referred to according to a lateral axis extending along the depicted bounding plane 406, merely for ease of description (e.g., is two-dimensional). Any of the features described with respect the two dimensional view can be extended to a three dimensional device, across any number of axes of the lateral plane For example, a misalignment can have an x-axis 110 and a y-axis 110 component for various connectors of paired contact array structures 108, which include offsets along the x-axis 110 and a y-axis 110.

The bottom substrate 404 includes an active surface 408 which connects to various metallization layers. The metallization layers can include, for example, an M0 layer having a via portion 410 and another conductive element portion 412, an M1 layer having a via portion 414 and another conductive element portion 416, and a terminal layer 418 (e.g., an M2 layer), the terminal layer 418 abutting the bonding plane 406. Various embodiments can employ additional or fewer metallization levels, inter-layer connections, or other features.

The depicted terminal layer 418 of the bottom substrate 404 includes contacts, depicted herein as first via structure 420 and second via structures 422 extending, vertically to the bonding plane 406. The first via structure 420 and second via structure 422 connect to a same conductive element 424. A further via structure 426 of the depicted terminal layer 418 connects to another conductive element 428. Any number of via structures of a contact array structure 108 can connect to any number of other conductive elements. The first 420, second 422, and third via structures 426 are associated with a same logical net (e.g., are configured to connect to each other), and may be referred to as a contact array structure 108. A corresponding contact array structure 108 of the top substrate 402 includes a fourth 430, fifth 432, and sixth 434 via structure. The top substrate 402 further includes a seventh via structure 436. The seventh via structure 436 is not connected to a logical net of the upper substrate 402. For example, the seventh via structure 436 can be generated incident to a design rule check (DRC) guideline instantiating a percentage of metal along the surface (e.g., a minimum micropillar density), can be a test connection, or can be configured to connect to a corresponding contact of the bottom substrate 404 to mechanically support a bonding of the bonding plane 406.

Each of the first 420, second 422, and third via structures 426 are configured to connect to one or more corresponding via structures, and, particularly, to the fourth 430, fifth 432, and sixth via structures 434. For example, the second 422 via structure can be configured to interface with the fifth via structure 432 in alignment therewith. The first via structure 420 can be configured to interface with the fourth via structure 430, offset therefrom. The third via structure 426 can be configured to interface with the sixth via structure 434, offset therefrom in a direction opposite of the offset between the first via structure 420 and the fourth via structure 430. The offsets can maintain a total resistance according to various misalignments of one or more of the contacts that may occur during or incident to wafer bonding, as a result of, for example, bonding operations, or variations between the top 402 and bottom 404 substrates.

The depicted portion of the upper substrate 402 and lower substrate 404 are laterally misaligned by an offset 440. The offset can originate from a shifted wafer 102 or die 106, or from a stretched or otherwise deformed substrate, in some instances. The offset 440 may be shared for various contacts of a contact array structure 108, or can vary therebetween. For example, an offset 442 between the second contact 422 and the fifth contact 432 can be equal to, greater than, or less than the offset 440 measured at another position along the semiconductor device 400. As depicted, as may frequently be the case, especially for proximal connections of a contact array structure 108, the offsets between the various contacts are similar. The offset 440 reduces a contact area between bonding pads of the second contact 422 and the fifth contact 432 so as to increase a contact resistance, and may further impact various SI properties. Such impacts of the offset 440 may be diminished or reversed with regard to a connection between the third contact 426 and the sixth contact 434, which, as depicted, are offset 446 a lesser amount than in a nominally aligned embodiment. Conversely, the depicted connection between the first contact 420 and the fourth contact 430 may suffer from increased resistance, according to an offset 444 which exceeds a distance in an aligned embodiment.

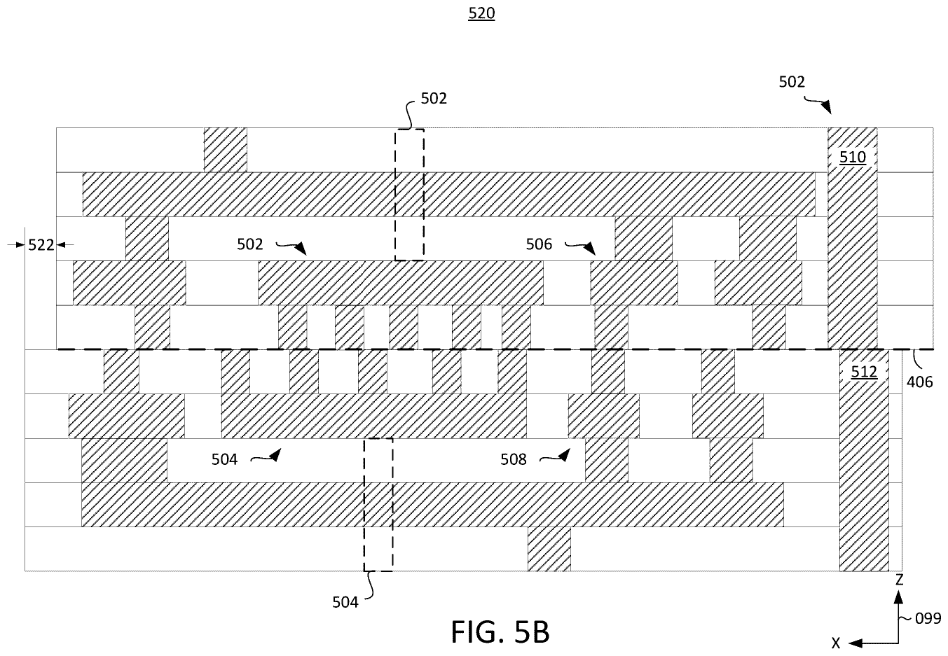

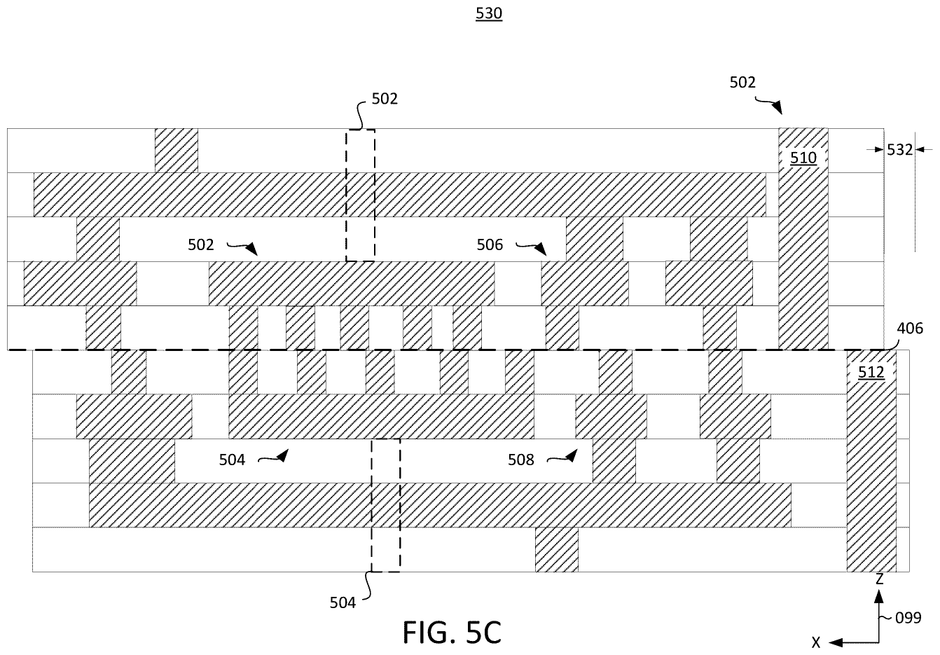

FIG. 5A illustrates a cross sectional view 500 of a bonded substrate pair including paired contact array structures 108, in accordance with some embodiments. The depicted view 500 is provided to depict a nominal position of various contacts, such that misalignments depicted, hereinafter, may be better understood. The view 500 includes various contact array structures 108. Varying embodiments can include any number of contact array structures 108, such as the structures described herein, or modifications thereof. The view includes two arbitrary substrates (e.g., frames or other carriers, wafers 102, or so forth) bonded at a bonding plane 406.

Particularly, the view 500 includes a first contact array structure 502 configured to interface with a second contact array structure 504. The various contacts of the first contact array structure 502 and the second contact array structure 504 are located proximal to each other, and are connected to a same conductive element. A central contact of the first contact array structure 502 is configured to align with a central contact of the second contact array structure 504. Further contacts are configured with varying offsets. Each of the first contact array structure 502 and the second contact array structure 504 include a portion, depicted as a dashed line, which is not present in the depicted cut plane. Further interconnections, contacts, or other portions of the various contact array structures 108 may exist away from the depicted cut plane (e.g., behind, or in front of the depicted view).

The contacts of the first contact array structure 502 or the second contact array structure 504 can be spaced according to a minimum pitch distance of a process, or another distance. The distance can be the same in one or more lateral dimensions, such as the depicted lateral dimension, or another lateral dimension into or out of the page.

The view 500 further includes a third contact array structure 506 configured to interface with a fourth contact array structure 508. The various contacts thereof are located disaggregated across the view, where the contacts thereof are laterally separated by various contacts of the first contact array structure 502. The contacts of the third contact array structure 506, then, are spaced greater than a minimum pitch distance therefor. Particularly, the aligned contact pair of the third contact array structure 506 and fourth contact array structure 508 are separated by the depicted contacts of the first contact array structure 502 and the second contact array structure 504. The separation may reduce an effect of local misalignment, maintain an existing routing of a net connecting to multiple device terminals, locations on a panel 104, or so forth.

The depicted contacts are larger than the contacts of the first contact array structure 502 and the second contact array structure 504. In various embodiments, contacts of one or more contact array structures 108 may vary in one or more lateral dimensions. For example, the contacts of the fifth contact array structure 510 and sixth contact array structure 512 are larger still, at least in the depicted lateral dimension.

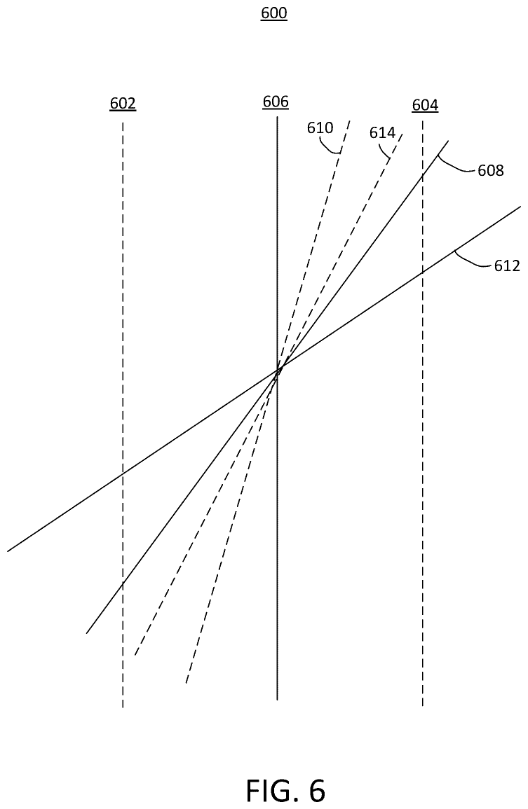

A single contact of the fifth contact array structure 510 is shown interfacing with a single contact of the sixth contact array structure 512. The depicted contacts can be the only contacts of the respective contact array structures 510, 512, or further contacts can be disposed away from the depicted view. For example, further contacts can be disposed a minimum pitch distance from the depicted contacts, or a distance greater than the minimum distance. In some embodiments, the various contracts can be laterally separated by other contacts. Such separation can be directly along an line between the contacts, or perpendicularly offset therefrom. The offset can be based on an expected magnitude of shift. For example, the offset can be on an order of a size of a misalignment, such as to correspond to a yield line portion of FIG. 6. Thus, one or more contacts can be sized to accommodate shifting based on a pad size.

FIGS. 5B, and 5C illustrate off-nominal alignments of the paired contact array structures 108 of FIG. 5A, in accordance with some embodiments. Referring now to FIG. 5B, an offset 522 may offset the depicted view 520 a similar amount in a same direction. Rightmost contacts of the first contact array structure 502 and second contact array structures 504 are generally aligned, wherein corresponding leftmost contacts do not connect to each other. Instead, as depicted, the leftmost contact of the first contact array structure 502 connects to another contact of the second contact array structure 504. Such correspondence of contacts may not be present at every junction, for example, corresponding contact array structures 108 can include four and five contacts, respectively, wherein an impedance budget is met by a summation of one or more connections therebetween.

The nominally aligned contact of the third contact array structure 506 is marginally connected to a corresponding contact of the fourth contact array structure 508. Corresponding contacts which are nominally offset in the same direction as the offset 522 are not connected, and corresponding contacts which are nominally offset in the opposite direction as the offset 522 are generally aligned according to the depicted view 520, though the degree of alignment or misalignment will vary according to a pitch spacing, lateral dimension, magnitude, direction, or uniformity of a misalignment, and so forth.

Referring now to FIG. 5C, a view 530 of another offset 532 is depicted. The offset amount can be similar in magnitude and opposite in direction, relative to the offset 522 of FIG. 5B. Leftmost contacts of the first contact array structure 502 and second contact array structure 504 are generally aligned, wherein corresponding rightmost contacts do not connect to each other. Instead, as depicted, the rightmost contact of the first contact array structure 502 connects to another contact of the second contact array structure 504. An alignment of the contacts of the third 506 and fourth contact array structures are inverted such that the nominally aligned contact is marginally connected in an opposite direction relative to FIG. 5B. Corresponding contacts which are nominally offset in the same direction as the offset 532 are not connected, and corresponding contacts which are nominally offset in the opposite direction as the offset 532 are generally aligned according to the depicted view 530. The offset 532 causes the single contacts of the fifth contact array structure 510 to laterally deviate from the single contact of the sixth contact array structure 512.

FIG. 6 is a graphical depiction 600 of yield corresponding to contact array structures 108, in accordance with some embodiments. The graphical depiction 600 represents a measured or estimated value of a DC resistance of one or more nets of the device, as compared to a lower specification limit 602 and upper specification limit 604. The lower specification limit 602 can correspond to, for example, an undesired connection (e.g., short circuits). The upper specification limit 604 can correspond to, for example, a maximum aggregate resistance for a contact array structure 108. The resistance provided herein is merely illustrative of various characteristics that may vary according to an offset having an upper and lower limit, such as characteristic impedances, wafer stress, other impedances, etc.

A first yield line 606 depicts a probability distribution of misalignment for a nominally aligned contact. Because the entirety of the probability distribution is bounded by the lower specification limit 602 and upper specification limit 604, no misalignments occur in excess of a threshold. A second yield line 608 corresponds to a misalignment for a device lacking shifted multi-via connections. As depicted, a portion of the probability distribution falls beyond the specification limits 602, 604, such that an expected yield loss due to the misalignment can correspond to the portion of the line exceeding the specification limits 602, 604. The distribution may vary according to a substrate location. For example, the peripheral portions of a substrate may suffer from misalignments more than centrally located portions.

A third yield line 610 depicts a yield, according to the same misalignment as the second yield line 608, for an embodiment including shifted multi-via connections. A fourth yield line 612 corresponds to an embodiment lacking shifted multi-via connections, for a greater magnitude misalignment, and exhibits a greater distribution of connections exceeding or subceeding specification limits 602, 604. A fifth yield line 614 depicts a yield, according to the same misalignment as the fourth yield line 612, for the embodiment including shifted multi-via connections. Of course, a linearity, yield rate, and other such data will vary from the depicted illustrative example according to a particular attachment of contacts, other process operations, and so forth.

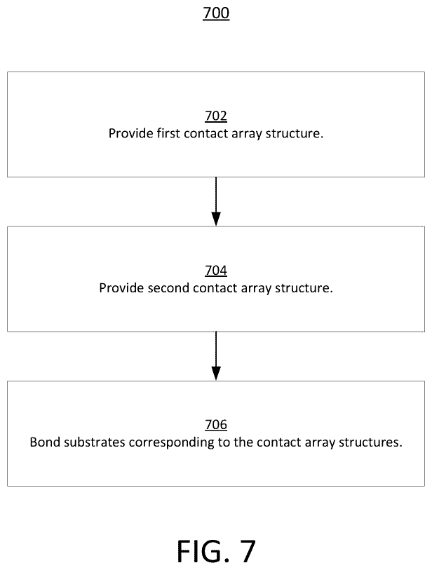

FIG. 7 is a flow chart of a method 700 for making a semiconductor device, in accordance with some embodiments. In brief overview, the method 700 starts with operation 702 of providing a first contact array structure 108. The method 700 continues to operation 704 of providing a second contact array structure 108. The method 700 proceeds to operation 706 of bonding substrates corresponding to the first and second contact array structures 108.

Referring again to operation 702, the first contact array structure 108 can be provided in a substrate, such as a semiconductor substrate. For example, the first contact array structure 108 can be impregnated within the substrate, such as within various metallization layers formed over an active surface of the substrate. The contact array structure 108 can be one of any number of contact array structures 108 of the substrate. For example, the substrate can include various dies 106, which may be connected (as in the case of a wafer 102), or disconnected (as in the case of various die carriers, referred to generally as panels 104). Each contact array structure 108 can include multiple contacts (e.g., copper pillars) configured to connect to another contact array structure 108 of another substrate, via a bonding pad thereof. The various contacts can be proximal to each other (e.g., according to a regularly repeating pattern, such as a pattern defined by a minimum bonding pad pitch). The various contacts can be disaggregated across the surface of the substrate, such as across a surface of each die 106. The substrate can contain any number of other contacts which are also configured to connect to a corresponding contact. The substrate can include further contacts, such as for test pads or other functions. Some contacts of the device can be contacts of contact array structures 108, and other contacts may not be.

Referring again to operation 704, the second contact array structure 108 can be provided in another substrate. The second contact array structure 108 includes contacts configured to interface (e.g., electrically connect to) the contacts of the first contact array structure 108. The contact array structures 108 can include various portions, any of which can include (or omit) a nominally aligned contact, and a nominally offset contact, where the alignment of the second contact array structure 108 is relative to a position of the first contact array structure 108. The various contacts between the first contact array structure 108 and the second contact array structure 108 may be referred to as corresponding contacts, wherein the contacts are configured to connect to a same net. For example, the corresponding contacts can include a nominally corresponding contact, which is nominally fully aligned, a nominally corresponding contact, which is nominally partially aligned (e.g., nominally offset less than a lateral dimension of the contact), or nominally do not include overlapping footprints, but which may electrically connect in a functional semiconductor device. An (e.g., intentionally shifted) offset contact can be offset based on a shift in either (or both) corresponding contacts. That is either of the first or second wafer can include a contact array structure 108 which may be adjusted to cause the offset. More generally, one skilled in the art will realize that an offset between two surfaces is dependent upon adjustments made to either the first surface, the second surface, or both surfaces; adjustments to either surface may result in a concurrent alteration in the existing offset, influencing the relative positions and dimensions of the surfaces.

Referring again to operation 706, the substrates comprising the respective first and second substrates are bonded to each other. For example, where bonding is originated by a mechanical process at the center of the wafer 102 (e.g., by a striker), the center of the substrates may be aligned, or substantially aligned. In some instances, the center may be offset, such as according to a mis-loading of a wafer 102 onto a wafer chuck, a tolerance limit of a wafer chuck, or otherwise. Further, during the bonding process, various portions of the wafer 102 can misalign according to a same offset, or intra-substrate skew (e.g., wafer distortion, non-linearity of dies 106 in a frame, or so forth). Thus, the nominally aligned contacts may be at least somewhat offset, and the nominally offset contacts can connect with a greater than nominal area, corresponding to a reduced contact resistance, which may otherwise improve various signaling characteristics.

In some instances, a measurement of an offset is detected along one or more portions of the respective substrate to generate misalignment data. Various actions can be taken based on the misalignment data. For example, inoperable parts can be discarded, at risk parts can be discarded or selectively used (e.g., according to additional testing or in low risk applications, such as devices including few semiconductor devices). Reduced performance devices can be operated at reduced performance. For example, the first and second substrate can include a processor or memory device, which can be operated at a lower frequency. High performance devices can be selectively used in high performance or high reliability applications.

Misalignment data can be used for process optimization. For example, if a semiconductor device is frequently misaligned in a first direction, the root cause may be investigated or the interconnect structure can be intentionally offset in a direction opposite the first direction to negate the misalignment. Such misalignment data may also be employed to determine a placement of vias. For example, where misalignment is frequent along a radial axis of a wafer 102, but rare in an axis perpendicular thereto, non-symmetrical contact array structures 108 can be formed which are configured to preferentially correct for misalignment in the radial outward direction, such as by including additional offsets along the radial axis, or omitting a portion of contacts (e.g., to increase density of logical connections). Misalignment data may also be employed to select one or more contacts. For example, contact array structures 108 can correspond to connections, such as clock connections or strobes can which can be selectively pruned (e.g., via a one-time fuse) responsive to an alignment, which can reduce reflections or otherwise affect SI properties.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer 102, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method comprising:
providing a first contact array structure on a first substrate, the first contact array structure comprising a plurality of first contacts;
providing a second contact array structure on a second substrate, the second contact array structure comprising a plurality of second contacts configured to interface with the plurality of first contacts; and
bonding the first substrate to the second substrate,
wherein portions of the first contact array structure, the second contact array structure, or both the first and second contact array structures are intentionally shifted to compensate for misalignment that occurs during the bonding of the first substrate to the second substrate.

2. The method of claim 1, wherein the first substrate is a wafer.

3. The method of claim 1, wherein the first substrate is a panel comprising a plurality of semiconductor dies.

4. The method of claim 1, wherein the first contact array structure comprises:
two contacts laterally separated by other contacts of the first substrate.

5. The method of claim 1, wherein the first contact array structure comprises bonding pads with a bonding pad pitch, the method further comprising shifting a via-structure pattern on at least one of the first and second substrate to specified distances based on the bonding pad pitch.

6. The method of claim 1, wherein the first contact array structure comprises multi-via connections with pattern shifts provided either in a regular array structure or in a disaggregated assortment across the bonding interface.

7. The method of claim 2, wherein:
the first substrate comprises a third contact array structure configured to electrically connect to a fourth contact array structure of the second substrate, the third contact array structure disposed radially outward from the first contact array structure; and
a nominal offset of the third contact array structure, relative to the fourth contact array structure, exceeds a nominal offset of the first contact array structure, relative to the second contact array structure.

8. The method of claim 1, further comprising:
detecting an indication of an impedance between the first contact array structure and the second contact array structure.

9. A system comprising:
a first substrate comprising a plurality of first contacts of a first contact array structure, the plurality of first contacts coupled to a first net of the first substrate; and
a second substrate comprising a plurality of second contacts of a second contact array structure, the plurality of second contacts coupled to a second net of the second substrate, and the second contact array structure configured to interface with the first contact array structure, wherein at least one of the plurality of first contacts is offset from a corresponding one of the plurality of second contacts.

10. The system of claim 9, wherein the first contact array structure comprises a contact which:
is configured to connect to a corresponding contact of the second contact array structure; and
is not offset from the corresponding contact.

11. The system of claim 9, wherein:
a first one of the plurality of first contacts is configured to couple with a first one of the plurality of second contacts, according to an off-nominal position of the first substrate relative to the second substrate, the coupling associated with a first resistance; and
the first one of the plurality of first contacts is configured to couple with the first one of the plurality of second contacts, according to a nominal position of the first substrate relative to the second substrate, the coupling associated with a second resistance greater than the first resistance.

12. The system of claim 9, wherein:
a lateral dimension, along a first lateral axis, of a first one of the plurality of first contacts exceeds a magnitude of an expected offset.

13. The system of claim 9, wherein:
a quantity of the plurality of first contacts is equal to a quantity of the plurality of second contacts.

14. The system of claim 9, wherein:
each of the plurality of first contacts have a same footprint; and
each of the plurality of second contacts have the same footprint.

15. The system of claim 9, wherein:
the plurality of first contacts have a common pitch.

16. A structure comprising:
a first substrate; and
a second substrate bonded to the first substrate along a bonding plane;
wherein the first substrate comprises a first contact array structure having:
a first contact configured to interface with a second contact of the second substrate; and
a third contact configured to interface with a fourth contact of the second substrate, the first contact and the second contact spaced a first distance along a first axis of the bonding plane; and
wherein the second substrate comprises a second contact array structure having:
the second contact; and
the fourth contact, the second contact and the fourth contact spaced a second distance, different from the first distance, along the first axis of the bonding plane.

17. The structure of claim 16, further comprising:
a fifth contact of the first substrate configured to interface with a sixth contact of the second substrate, the fifth contact spaced from the first contact a third distance along a second axis of the bonding plane, different from the first axis; and
the sixth contact spaced from the second contact a fourth distance, different from the third distance, along the second axis.

18. The structure of claim 17, wherein:
the first distance is equal to the third distance;
the second distance is equal to the fourth distance; and
the first axis is perpendicular to the second axis.

19. The structure of claim 16, wherein:
the first substrate is a wafer, the wafer further comprising:
a third contact array structure disposed radially outward from the first contact array structure, the third contact array structure comprising a plurality of contacts spaced by third distance greater than the first distance.

20. The structure of claim 16, wherein:
wherein the first contact array structure comprises multi-via connections with pattern shifts provided either in a regular array structure or in a disaggregated assortment across the bonding interface.
